(19) United States
(12) Patent Application Publication
(10) Pub. No.: US 2025/0174541 A1
(43) Pub. Date: May 29, 2025

(54) SEMICONDUCTOR PACKAGE INCLUDING CONDUCTIVE POST AND METHOD OF MANUFACTURING THE SAME

(71) Applicant: SAMSUNG ELECTRONICS CO., LTD., Suwon-si (KR)

(72) Inventors: Jing Cheng Lin, Suwon-si (KR); Youngkun Jee, Suwon-si (KR); Jongho Park, Suwon-si (KR); Jaemok Jung, Suwon-si (KR); Taeoh Ha, Suwon-si (KR)

(73) Assignee: SAMSUNG ELECTRONICS CO., LTD., Suwon-si (KR)

(21) Appl. No.: 18/957,085

(22) Filed: Nov. 22, 2024

(30) Foreign Application Priority Data
Nov. 27, 2023 (KR) 10-2023-0167154

(51) Int. Cl. H01L 23/498; H01L 21/48; H01L 21/56; H01L 23/31; H01L 25/03; H01L 25/18; H05K 1/11; H05K 3/36; H05K 3/40; H10B 80/00

(52) U.S. Cl. CPC H01L 23/49838; H01L 21/4853; H01L 21/56; H01L 23/3142; H01L 23/49811; H01L 23/49894; H05K 1/11; H05K 3/368; H05K 3/4007; H01L 21/4857; H01L 21/486; H01L 23/49822; H01L 25/03; H01L 25/18; H05K 1/113; H05K 2201/042; H05K 2201/10242; H10B 80/00

(57) ABSTRACT

A semiconductor package includes: a first wiring structure including at least one first wiring pattern and a first insulating layer including the first wiring pattern therein; a second wiring structure including at least one second wiring pattern and a second insulating layer including the second wiring pattern therein; a semiconductor chip between the first wiring structure and the second wiring structure; a molding layer between the first wiring structure and the second wiring structure, the molding layer comprising the semiconductor chip therein; and a conductive post penetrating the molding layer and configured to electrically connect the first wiring structure to the second wiring structure, wherein the conductive post includes: a body extended through the molding layer in a vertical direction; and a bonding surface on a side surface of the body and having a greater roughness than an upper surface and a lower surface of the conductive post.

### CROSS-REFERENCE TO RELATED APPLICATION

This application is based on and claims priority to Korean Patent Application No. 10-2023-0167154, filed on Nov. 27, 2023, in the Korean Intellectual Property Office, the disclosure of which is incorporated by reference herein in its entirety.

### BACKGROUND

The disclosure relates to a semiconductor package and a method of manufacturing the same, and more specifically, to a fan-out semiconductor package and a method of manufacturing the same.

Due to the significant progress in the electronics industry and the demand of users, electronic devices are becoming more and more compact and multi-functional and have greater capacity, thus requiring a highly integrated semiconductor chip.

Accordingly, a semiconductor package having connection terminals, with which connection reliability is ensured, is designed for highly integrated semiconductor chips in which the number of input/output (I/O) connection terminals is increased; for example, to prevent interference among connection terminals, a fan-out semiconductor package in which a distance between the connection terminals is increased is being developed.

### SUMMARY

The disclosure provides a semiconductor package with improved reliability and improved structural stability and a method of manufacturing the same.

According to an aspect of the disclosure, there is provided a semiconductor package which may include: a first wiring structure including at least one first wiring pattern and a first insulating layer including the first wiring pattern therein; a second wiring structure including at least one second wiring pattern and a second insulating layer including the second wiring pattern therein; a semiconductor chip between the first wiring structure and the second wiring structure; a molding layer between the first wiring structure and the second wiring structure, the molding layer including the semiconductor chip therein; and a conductive post penetrating the molding layer and configured to electrically connect the first wiring structure to the second wiring structure, wherein the conductive post includes: a body extended through the molding layer in a vertical direction; and a bonding surface on a side surface of the body and having a greater roughness than an upper surface and a lower surface of the conductive post.

According to another aspect of the disclosure, there is provided a method of manufacturing a semiconductor package. The method may include: forming a first wiring structure including at least one first wiring pattern and a first insulating layer including the first wiring pattern therein; forming a conductive post on the first wiring structure; mounting a semiconductor chip on the first wiring structure; forming a bonding surface on the conductive post; forming a molding layer on the conductive post and the semiconductor chip; and forming, on the molding layer, a second wiring structure including at least one second wiring pattern and a second insulating layer including the second wiring pattern therein, wherein the bonding surface has a greater roughness than an upper surface and a lower surface of the conductive post.

According to still another aspect of the disclosure, there is provided a semiconductor package which may include: a first wiring structure including at least one first wiring pattern and a first insulating layer including the first wiring pattern therein; a second wiring structure including at least one second wiring pattern and a second insulating layer including the second wiring pattern therein; a semiconductor chip between the first wiring structure and the second wiring structure; a molding layer between the first wiring structure and the second wiring structure, the molding layer including the semiconductor chip therein; and a conductive post penetrating the molding layer and configured to electrically connect the first wiring structure to the second wiring structure, wherein the conductive post includes: a body extended through the molding layer in a vertical direction; and a bonding surface on the body, the bonding surface including at least one protrusion protruding toward the molding layer and at least one recess.

### BRIEF DESCRIPTION OF DRAWINGS

Embodiments will be more clearly understood from the following detailed description taken in conjunction with the accompanying drawings in which:

FIG. 1 is a cross-sectional view of a semiconductor package according to one or more embodiments;

FIG. 2 is an enlarged cross-sectional view of a region EX1 of FIG. 1;

FIGS. 3 to 12 are cross-sectional views showing a method of manufacturing a semiconductor package, according to one or more embodiments; and

FIG. 13 is a cross-sectional view of a semiconductor package according to one or more embodiments.

### DETAILED DESCRIPTION OF EMBODIMENTS

Hereinafter, embodiments of the disclosure will be described in detail with reference to the accompanying drawings. These embodiments are non-limiting example embodiments, and thus, the disclosure is not limited thereto and may be realized in various other forms.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present. As used herein, an expression “at least one of”' preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

The same reference numerals are used for the same constituent elements in the drawings, and duplicate descriptions thereof are omitted.

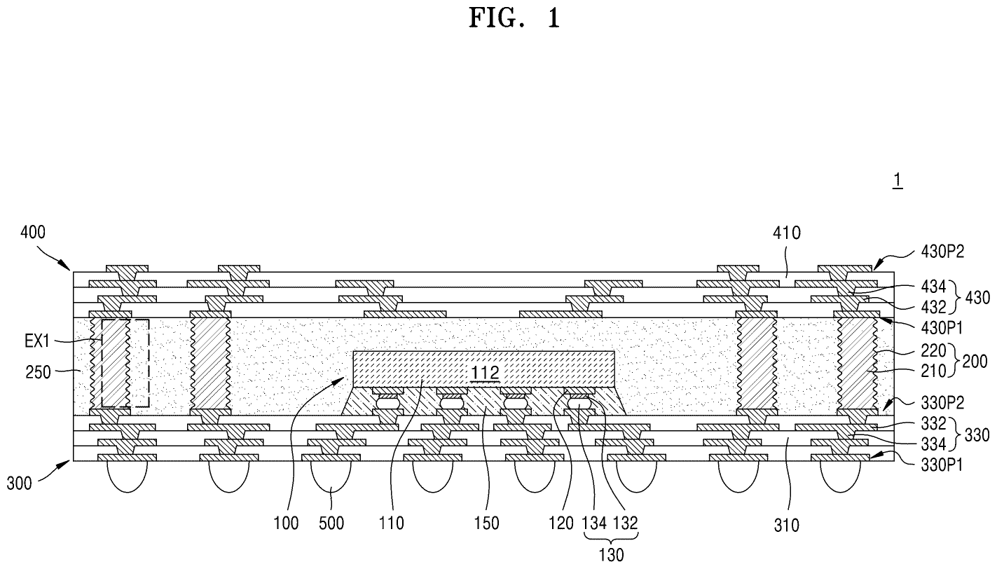

FIG. 1 is a cross-sectional view of a semiconductor package according to one or more embodiments.

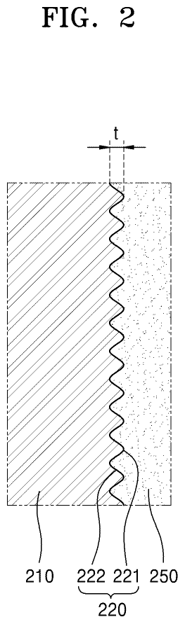

FIG. 2 is an enlarged cross-sectional view of a region EX1 of FIG. 1.

Referring to FIGS. 1 and 2, a semiconductor package 1 of the disclosure may include a first wiring structure 300, a second wiring structure 400 above the first wiring structure 300 in a vertical direction, and at least one semiconductor chip 100 arranged between the first wiring structure 300 and the second wiring structure 400.

In embodiments, the semiconductor package 1 of the disclosure may be a lower package of a package-on-package (PoP). The semiconductor package 1 may be a fan-out type semiconductor package in which a horizontal width and a horizontal area of the first wiring structure 300 are respectively greater than a horizontal width and a horizontal area of the at least one semiconductor chip 100. In some embodiments, the semiconductor package 1 may be a fan-out type wafer-level package (FOWLP) or a fan-out type panel-level package (FOPLP).

In some embodiments, at least one of the first wiring structure 300 and the second wiring structure 400 may be formed by a redistribution process. The first wiring structure 300 and the second wiring structure 400 may be respectively referred to as a first redistribution structure and a second redistribution structure, or may be respectively referred to as a lower redistribution structure and an upper redistribution structure.

The first wiring structure 300 may include a first redistribution insulating layer 310 and a plurality of first redistribution patterns 330. The first redistribution insulating layer 310 may surround the plurality of first redistribution patterns 330. In some embodiments as shown in FIG. 1, the first wiring structure 300 may include a plurality of first redistribution insulating layers 310 that are stacked in the vertical direction. The first redistribution insulating layer 310 may be formed from, for example, photo-imageable dielectric (PID) or photosensitive polyimide (PSPI). For example, the first wiring structure 300 may have a thickness of about 30 μm to about 50 μm.

The plurality of first redistribution patterns 330 may each include a plurality of first redistribution line patterns 332 and a plurality of first redistribution vias 334. The plurality of first redistribution patterns 330 may be, for example, a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), etc., or an alloy of these metals, but are not limited thereto. In embodiments, the plurality of first redistribution patterns 330 may be formed by stacking a metal or an alloy of metals on a seed layer including copper, titanium, titanium nitride, or titanium tungsten.

The plurality of first redistribution line patterns 332 may be arranged on at least one of an upper (or top) surface and a lower (or bottom) surface of the first redistribution insulating layer 310. For example, when the first wiring structure 300 includes a plurality of first redistribution insulating layers 310 that are stacked in the vertical direction as shown in FIG. 1, the plurality of first redistribution line patterns 332 may be disposed on an upper surface of the uppermost first redistribution insulating layer 310, may be disposed on a lower surface of the lowermost first redistribution insulating layer 310, and may be arranged in at least some regions between two adjacent first redistribution insulating layers 310 among the plurality of first redistribution insulating layers 310.

The plurality of first redistribution vias 334 may be respectively in contact with and connected to some of the plurality of first redistribution line patterns 332 through at least one first redistribution insulating layer 310. In embodiments, the plurality of first redistribution vias 334 may each have a tapered shape in which a horizontal width thereof increases from a lower surface to an upper surface thereof. For example, the plurality of first redistribution vias 334 may each have a horizontal width that increases towards the at least one semiconductor chip 100.

In embodiments, at least some of the plurality of first redistribution line patterns 332 may be formed together with some of the plurality of first redistribution vias 334 to form an integral body. For example, a first redistribution line pattern 332 and a first redistribution via 334, which is in contact with a lower surface of the first redistribution line pattern 332, may be formed together to form an integral body. For example, each of the plurality of first redistribution vias 334 may have a horizontal width that decreases away from a first redistribution line pattern 332 that constitutes the integral body.

Some of the plurality of first redistribution patterns 330, which are arranged adjacent to a lower surface of the first wiring structure 300, may be referred to as a plurality of first lower surface connection pads 330P1, and some of the plurality of first redistribution patterns 330, which are arranged adjacent to an upper surface of the first wiring structure 300, may be referred to as a plurality of first upper surface connection pads 330P2. For example, the plurality of first lower surface connection pads 330P1 may be some of the plurality of first redistribution line patterns 332, which are arranged adjacent to or on the lower surface of the first wiring structure 300, and the plurality of first upper surface connection pads 330P2 may be some of the plurality of first redistribution line patterns 332, which are arranged adjacent to or on the upper surface of the first wiring structure 300.

A plurality of external connection terminals 500 may be respectively attached to the plurality of first lower surface connection pads 330P1. The plurality of external connection terminals 500 may connect the semiconductor package 1 to the outside. In embodiments, each of the plurality of external connection terminals 500 may be a bump, a solder ball, etc. For example, each of the plurality of external connection terminals 500 may have a height of about 100 μm to about 180 μm. A plurality of chip connection members 130 may be attached to some of the plurality of first upper surface connection pads 330P2, and a plurality of conductive posts 200 may be attached to some others of the plurality of first upper surface connection pads 330P2.

The plurality of first upper surface connection pads 330P2 may be disposed on an upper surface of the first redistribution insulating layer 310. For example, when the first wiring structure 300 includes a plurality of first redistribution insulating layers 310 that are stacked in the vertical direction, the plurality of first upper surface connection pads 330P2 may be disposed on the upper surface of the uppermost first redistribution insulating layer 310.

The at least one semiconductor chip 100 may be attached onto the first wiring structure 300. A semiconductor chip 100 may include a semiconductor substrate 110 having an active surface and an inactive surface, which are opposite to each other, a semiconductor device 112 formed on the active surface of the semiconductor substrate 110, and a plurality of chip pads 120 disposed on a first surface of the semiconductor chip 100. For example, the semiconductor chip 100 may have a thickness of about 70 μm to about 200 μm. Herein, the first surface of the semiconductor chip 100 is opposite to a second surface of the semiconductor chip 100, and the second surface of the semiconductor chip 100 refers to the inactive surface of the semiconductor substrate 110. Because the active surface of the semiconductor substrate 110 is immediately adjacent to the first surface of the semiconductor chip 100, illustration of separately dividing the active surface of the semiconductor substrate 110 and the first surface of the semiconductor chip 100 is not provided.

In embodiments, the semiconductor chip 100 has a face-down arrangement, in which the first surface faces the first wiring structure 300, and may be attached onto the upper surface of the first wiring structure 300. In this case, the first surface of the semiconductor chip 100 may be referred to as a lower surface of the semiconductor chip 100, and the second surface of the semiconductor chip 100 may be referred to as an upper surface of the semiconductor chip 100. Unless otherwise specified herein, the term “upper surface” refers to a surface facing up in the drawings, and the term “lower surface” refers to a surface facing down in the drawings, in the vertical direction.

The plurality of chip connection members 130 may be arranged between the plurality of chip pads 120 of the semiconductor chip 100 and some of the plurality of first upper surface connection pads 330P2 of the first wiring structure 300. For example, each of the plurality of chip connection members 130 may be a solder ball or a micro bump. The semiconductor chip 100 and a first redistribution pattern 330 of the first wiring structure 300 may be electrically connected to each other via at least one chip connection member 130. Each of the plurality of chip connection members 130 may also include a Under Bump Metallurgy (UBM) layer 132 disposed on each of the plurality of chip pads 120, and a conductive cap 134 covering the UBM layer 132. For example, each of the plurality of chip connection members 130 may have a height of about 30 μm to about 40 μm. Each of the plurality of chip connection members 130 may be formed of a conductive material, for example, copper (Cu), aluminum (Al), silver (Ag), tin (Tin), gold (Au), or solder, but is not limited thereto.

The semiconductor substrate 110 may include a semiconductor material, such as silicon (Si) or germanium (Ge). Alternatively, the semiconductor substrate 110 may include a compound semiconductor material, such as silicon carbide (SiC), gallium arsenide (GaAs), indium arsenide (InAs), and indium phosphide (InP). The semiconductor substrate 110 may include a conductive region, for example, a well doped with impurities. The semiconductor substrate 110 may have various device isolation structures, such as a shallow trench isolation (STI) structure.

The semiconductor device 112 including a plurality of individual devices of various types may be formed on the active surface of the semiconductor substrate 110. The plurality of individual devices may include various microelectronic devices, for example, a metal-oxide-semiconductor field effect transistor (MOSFET) such as a complementary metal-oxide-semiconductor (CMOS) transistor, a system large scale integration (LSI), an active element, and a passive element. The plurality of individual devices may be electrically connected to the conductive region of the semiconductor substrate 110. The semiconductor device 112 may further include a conductive wiring or a conductive plug, each electrically connecting at least two of the plurality of individual devices to each other, or the plurality of individual devices to the conductive region of the semiconductor substrate 110. In addition, each of the plurality of individual devices may be electrically isolated from other neighboring individual devices by an insulating film.

In embodiments, the semiconductor chip 100 may include a logic device. For example, the semiconductor chip 100 may be a central processing unit (CPU) chip, a graphics processing unit (GPU) chip, or an application processor (AP) chip. In other embodiments, when the semiconductor package 1 includes a plurality of semiconductor chips 100, at least one of the plurality of semiconductor chips 100 may be a CPU chip, a GPU chip, or an AP chip, or at least one other semiconductor chip 100 may be a memory semiconductor chip including a memory device. For example, the memory device may be a non-volatile memory device, such as flash memory, phase-change random access memory (PRAM), magnetoresistive random access memory (MRAM), ferroelectric random access memory (FeRAM), or resistive random access memory (RRAM). The flash memory may be, for example, NAND flash memory or V-NAND flash memory. In embodiments, the memory device may be a volatile memory device, such as dynamic random access memory (DRAM) or static random access memory (SRAM).

The second wiring structure 400 may include a second redistribution insulating layer 410 and a plurality of second redistribution patterns 430. The second redistribution insulating layer 410 may surround the plurality of second redistribution patterns 430. The second redistribution insulating layer 410 may be formed from, for example, PID or PSPI.

In embodiments, a thickness of the second wiring structure 400 may be less than the thickness of the first wiring structure 300. For example, the second wiring structure 400 may have a thickness of about 20 μm to about 40 μm. In embodiments, the second wiring structure 400 may include a plurality of second redistribution insulating layers 410 that are stacked in the vertical direction. The plurality of second redistribution patterns 430 may include a plurality of second redistribution line patterns 432 and a plurality of second redistribution vias 434. The plurality of second redistribution patterns 430 may be a metal or an alloy of metals, but are not limited thereto. In embodiments, the plurality of second redistribution patterns 430 may be formed by stacking a metal or an alloy of metals on a seed layer.

The plurality of second redistribution line patterns 432 may be arranged on at least one of an upper surface and a lower surface of the second redistribution insulating layer 410. For example, when the second wiring structure 400 includes a plurality of second redistribution insulating layers 410 that are stacked in the vertical direction, the plurality of second redistribution line patterns 432 may be disposed on an upper surface of the uppermost second redistribution insulating layer 410, may be disposed on a lower surface of the lowermost second redistribution insulating layer 410, and may be arranged in at least some regions between two adjacent second redistribution insulating layers 410 among the plurality of second redistribution insulating layers 410.

Some of the plurality of second redistribution patterns 430, which are arranged adjacent to a lower surface of the second wiring structure 400, may be referred to as a plurality of second lower surface connection pads 430P1, and some of the plurality of second redistribution patterns 430, which are arranged adjacent to an upper surface of the second wiring structure 400, may be referred to as a plurality of second upper surface connection pads 430P2. For example, the plurality of second lower surface connection pads 430P1 may be some of the plurality of second redistribution line patterns 432, which are arranged adjacent to or on the lower surface of the second wiring structure 400, and the plurality of second upper surface connection pads 430P2 may be some of the plurality of second redistribution line patterns 432, which are arranged adjacent to or on the upper surface of the second wiring structure 400. In other embodiments, the plurality of second lower surface connection pads 430P1 may be some of the plurality of second redistribution vias 434, which are arranged adjacent to the lower surface of the second wiring structure 400.

In embodiments, when the semiconductor package 1 is a lower package of a PoP, an upper package of the POP may be connected to the plurality of second upper surface connection pads 430P2. For example, a plurality of package connection terminals may be arranged between the upper package and the plurality of second upper surface connection pads 430P2. In embodiments, each of the plurality of package connection terminals may be a bump, a solder ball, etc. The upper package may include an auxiliary semiconductor chip. The auxiliary semiconductor chip may be a memory semiconductor chip. For example, the auxiliary semiconductor chip may be a DRAM chip, an SRAM chip, a flash memory chip, an EPROM chip, a PRAM chip, an MRAM chip, or an RRAM chip. The plurality of conductive posts 200 may be attached to the plurality of second lower surface connection pads 430P1.

The plurality of second lower surface connection pads 430P1 may be disposed on the lower surface of the second redistribution insulating layer 410. For example, when the second wiring structure 400 includes a plurality of second redistribution insulating layers 410 that are stacked in the vertical direction, the plurality of second lower surface connection pads 430P1 may be disposed on the lower surface of the lowermost second redistribution insulating layer 410.

The plurality of second upper surface connection pads 430P2 may be disposed on the upper surface of the second redistribution insulating layer 410. For example, when the second wiring structure 400 includes a plurality of second redistribution insulating layers 410 that are stacked on each other, the plurality of second upper surface connection pads 430P2 may be disposed on the upper surface of the uppermost second redistribution insulating layer 410. The plurality of second upper surface connection pads 430P2 may protrude from the upper surface of the second redistribution insulating layer 410 in the vertical direction, that is, in a direction opposite to the semiconductor chip 100 and the first wiring structure 300. For example, when the second wiring structure 400 includes a plurality of second redistribution insulating layers 410 that are stacked in the vertical direction, the plurality of second upper surface connection pads 430P2 may protrude from the upper surface of the uppermost second redistribution insulating layer 410 in the vertical direction away from the semiconductor chip 100 and the first wiring structure 300. At least a portion of the upper surface and the side surface of each of the plurality of second upper surface connection pads 430P2 may not be in contact with the second redistribution insulating layer 410.

The plurality of second redistribution vias 434 may be respectively in contact with and connected to some of the plurality of second redistribution line patterns 432 through at least one second redistribution insulating layer 410. In embodiments, at least some of the plurality of second redistribution line patterns 432 may be formed together with some of the plurality of second redistribution vias 434 to form an integral body. For example, a second redistribution line pattern 432 and a second redistribution via 434, which is in contact with a lower surface of the second redistribution line pattern 432, may be formed together to form an integral body.

In embodiments, the plurality of second redistribution vias 434 may have a tapered shape in which a horizontal width thereof decreases from an upper surface to a lower surface thereof. For example, the plurality of second redistribution vias 434 may each have a horizontal width that decreases towards the at least one semiconductor chip 100. The plurality of first redistribution vias 334 and the plurality of second redistribution vias 434 extend in the same direction and may each have a horizontal width increases or decreases. For example, the plurality of first redistribution vias 334 and the plurality of second redistribution vias 434 may each have a tapered shape extending from the first wiring structure 300 toward the second wiring structure 400 and having a horizontal width that increases, or extending from the second wiring structure 400 toward the first wiring structure 300 and having a horizontal width that decreases.

The first redistribution insulating layer 310, a first redistribution pattern 330, a first redistribution line pattern 332, and a first redistribution via 334 may be respectively referred to as a first base insulating layer, a first wiring pattern, a first wiring line pattern, and a first wiring via, and the second redistribution insulating layer 410, a second redistribution pattern 430, a second redistribution line pattern 432, and a second redistribution via 434 may be respectively referred to as a second base insulating layer, a second wiring pattern, a second wiring line pattern, and a second wiring via.

A molding layer 250 may be disposed on the first wiring structure 300 and surround the at least one semiconductor chip 100. For example, the molding layer 250 may cover at least a portion of a side surface of the at least one semiconductor chip 100 and an upper surface thereof. The molding layer 250 may fill a space between the first wiring structure 300 and the second wiring structure 400. For example, the molding layer 250 may have a thickness of about 150 μm to about 300 μm. The molding layer 250 may include a polymer material. For example, the molding layer 250 may be a molding member including an epoxy molding compound (EMC). The molding layer 250 may contain a filler. For example, the filler may include a ceramic-based material having non-conductive insulating properties. In embodiments, the filler may include at least one of AlN, BN, Al203, SiC, and MgO. For example, the filler may be a silica filler or an alumina filler. For example, the molding layer 250 may include an epoxy-based material containing filler. An average diameter of the filler contained in the molding layer 250 may be about 3 μm to about 50 μm. A proportion of the filler contained in the molding layer 250 may be about 60 wt % to about 90 wt %.

In embodiments, an underfill layer 150 surrounding the plurality of chip connection members 130 may be arranged between the semiconductor chip 100 and the first wiring structure 300. In embodiments, the underfill layer 150 may fill a space between the at least one semiconductor chip 100 and the first wiring structure 300 and cover a portion of a lower side of the side surface of the at least one semiconductor chip 100. The underfill layer 150 may include, for example, an epoxy resin formed by a capillary under-fill method. In embodiments, the underfill layer 150 may be a non-conductive film (NCF).

In embodiments, the at least one semiconductor chip 100 and the second wiring structure 400 may be spaced apart from each other in the vertical direction. For example, the upper surface of the at least one semiconductor chip 100 may be arranged at a vertical level that is lower than the lower surface of the second wiring structure 400. The molding layer 250 may fill a space between the at least one semiconductor chip 100 and the second wiring structure 400.

In embodiments, side surfaces of the first wiring structure 300, side surfaces of the molding layer 250, and side surfaces of the second wiring structure 400 may be aligned, respectively, with one another in the vertical direction. For example, one side surface of the first wiring structure 300, one side surface of the molding layer 250, and one side surface of the second wiring structure 400, which correspond to one another, may be coplanar with one another.

The plurality of conductive posts 200 may electrically connect the first wiring structure 300 to the second wiring structure 400 through the molding layer 250. The molding layer 250 may surround the plurality of conductive posts 200.

The plurality of conductive posts 200 may be arranged between the first wiring structure 300 and the second wiring structure 400 so as to be spaced apart from the at least one semiconductor chip 100 in the horizontal direction. For example, the plurality of conductive posts 200 may be spaced apart from the at least one semiconductor chip 100 in the horizontal direction and arranged around the at least one semiconductor chip 100. The plurality of conductive posts 200 may be arranged between the plurality of first upper surface connection pads 330P2 and the plurality of second lower surface connection pads 430P1. Lower surfaces of the plurality of conductive posts 200 may be in contact with the plurality of first upper surface connection pads 330P2 of the first wiring structure 300 and electrically connected to the plurality of first redistribution patterns 330, and upper surfaces of the plurality of conductive posts 200 may be in contact with the plurality of second lower surface connection pads 430P1 of the second wiring structure 400 and electrically connected to the plurality of second redistribution patterns 430, respectively. For example, a height of each of the plurality of conductive posts 200 may be about 150 μm to about 300 μm, and a horizontal width of each of the plurality of conductive posts 200 may be about 120 μm to about 200 μm. An aspect ratio, that is, a ratio of height to horizontal width, of each of the plurality of conductive posts 200 may be greater than 1.

The lower surface of each of the plurality of conductive posts 200 may be in contact with an upper surface of a first upper surface connection pad 330P2. The upper surface of each of the plurality of conductive posts 200 may be in contact with a lower surface of a second lower surface connection pad 430P1. In embodiments, a horizontal width and a horizontal area of a first upper surface connection pad 330P2 that is in contact with a conductive post 200 may be greater than a horizontal width and a horizontal area of the conductive post 200, respectively. In embodiments, a horizontal width and a horizontal area of a second lower surface connection pad 430P1 that is in contact with a conductive post 200 may be greater than a horizontal width and a horizontal area of the conductive post 200, respectively. For example, an entire lower surface of a conductive post 200 may be in contact with the upper surface of a first upper surface connection pad 330P2, and a portion of the upper surface of the first upper surface connection pad 330P2 may not be in contact with the plurality of conductive posts 200. As another example, an entire upper surface of a conductive post 200 may be in contact with the lower surface of a second lower surface connection pad 430P1, and a portion of the lower surface of the second lower surface connection pad 430P1 may not be in contact with the plurality of conductive posts 200.

Each of the plurality of conductive posts 200 may include a body 210 and a bonding surface 220 surrounding the body 210. The body 210 may extend in the vertical direction. The body 210 may have a pillar shape having a circular, elliptical, or polygonal-shaped horizontal cross-section and extending in the vertical direction.

In embodiments, the bonding surface 220 may be formed on a side surface of the body 210. Herein, the bonding surface 220 is disclosed as being formed on an entire side surface of the body 210, but the disclosure is not limited thereto. For example, the bonding surface 220 may be formed on only a portion of the side surface of the body 210. The bonding surface 220 may not be formed on a lower surface and an upper surface of the body 210. For example, the bonding surface 220 may have a cylindrical shell shape with open top and open bottom, and the body 210 may have a cylindrical shape that fills the interior of the bonding surface 220.

According to one or more other embodiments, the bonding surface 220 may be not a separate layer but just the side surface of the body 210, in which case the body 210 and the bonding surface 220 may be a single continuum structure formed of the same metal or metal compound without a connection surface, a boundary or an interface therebetween.

In embodiments, the bonding surface 220 may include a rough surface. The bonding surface 220 may include a plurality of protrusions 221 and a plurality of recesses 222, and the plurality of protrusions 221 and the plurality of recesses 222 may constitute the rough surface. The plurality of protrusions 221 may protrude from the body 210 toward the molding layer 250 in the horizontal direction. The plurality of recesses 222 may be respectively arranged between the plurality of protrusions 221 that are adjacent to each other. For example, the plurality of protrusions 221 and the plurality of recesses 222 may be alternately arranged in the vertical direction.

The bonding surface 220 may have a greater roughness than the upper surface and/or the lower surface of a conductive post 200, not being limited thereto.

In embodiments, sizes or shapes of the plurality of protrusions 221 may be different from sizes or shapes of a recess 222. Because the sizes or the shapes of the plurality of protrusions 221 and the plurality of recesses 222 are different, the bonding surface 220 may have a non-uniform cross-section. At this time, thicknesses of the plurality of protrusions 221 in the horizontal direction may be different. For example, a thickness t of each of the plurality of protrusions 221 in the horizontal direction may be about 10 nm to about 1 μm.

In embodiments, the sizes and the shapes of the plurality of protrusions 221 may be the same as the sizes and the shapes of the plurality of recesses 222. Because the sizes and the shapes of the plurality of protrusions 221 and the plurality of recesses 222 are the same, the bonding surface 220 may have a uniform cross-section. At this time, thicknesses of the plurality of protrusions 221 in the horizontal direction may be equal to each other. For example, the thickness t of each of the plurality of protrusions 221 in the horizontal direction may be about 10 nm to about 1 μm.

In embodiments, the bonding surface 220 may be in contact with the molding layer 250, whereas the body 210 may not be in contact with the molding layer 250. The bonding surface 220 may be arranged between the body 210 and the molding layer 250. The body 210 and the molding layer 250 may be spaced apart from each other with the bonding surface 220 therebetween.

In embodiments, the molding layer 250 may be in contact with the bonding surface 220. For example, the molding layer 250 may be in contact with the plurality of protrusions 221 and the plurality of recesses 222. Because the bonding surface 220 includes the rough surface including the plurality of protrusions 221 and the plurality of recesses 222, a cross-sectional area where the molding layer 250 is in contact with the bonding surface 220 may increase. Because the cross-sectional area where the molding layer 250 is in contact with the bonding surface 220 increases, a bonding force between the molding layer 250 and the plurality of conductive posts 200 may increase. Because the cross-sectional area where the molding layer 250 is in contact with the bonding surface 220 increases, delamination that occurs at an interface between the molding layer 250 and the plurality of conductive posts 200 may be reduced. Structural stability and reliability of the semiconductor package 1 may be improved by eliminating or minimizing the delamination that occurs at the interface between the molding layer 250 and the plurality of conductive posts 200.

The semiconductor package 1 of the disclosure may have improved structural stability and reliability by improving a stress and a bonding force between the plurality of conductive posts 200 and the molding layer 250.

In embodiments, an oxide film (not shown) surrounding the plurality of conductive posts 200 may be included. The oxide film may cover the side surface of a conductive post 200. In embodiments, the oxide film may be conformally formed on a side surface of the bonding surface 220 of the conductive post 200.

The plurality of first upper surface connection pads 330P2 may protrude from the upper surface of the first redistribution insulating layer 310 toward the semiconductor chip 100 and the second wiring structure 400 in the vertical direction. For example, when the first wiring structure 300 includes a plurality of first redistribution insulating layers 310 that are stacked in the vertical direction, the plurality of first upper surface connection pads 330P2 may protrude from the upper surface of the uppermost first redistribution insulating layer 310 toward the semiconductor chip 100 and the second wiring structure 400 in the vertical direction. At least a portion of the upper surface and a side surface of each of the plurality of first upper surface connection pads 330P2 may not be in contact with the first redistribution insulating layer 310.

The molding layer 250 may surround at least a portion of the side surface of each of the plurality of first upper surface connection pads 330P2 and a portion of the upper surface thereof. The remaining portion of the upper surface of each of the plurality of first upper surface connection pads 330P2 may be on each of the plurality of conductive posts 200. The plurality of first lower surface connection pads 330P1 may not protrude from the lower surface of the lowermost first redistribution insulating layer 310 in the vertical direction. In embodiments, lower surfaces of the plurality of first lower surface connection pads 330P1 and the lower surface of the lowermost first redistribution insulating layer 310 may be arranged at the same vertical level and thus may be coplanar with each other.

The plurality of second lower surface connection pads 430P1 may not protrude from the lower surface of the lowermost second redistribution insulating layer 410 in the vertical direction. The second redistribution insulating layer 410 may surround a side surface of each of the plurality of second lower surface connection pads 430P1. In embodiments, the lower surfaces of the plurality of second lower surface connection pads 430P1 and the lower surface of the lowermost second redistribution insulating layer 410 may be arranged at the same vertical level and thus may be coplanar with each other.

The molding layer 250 may be on a portion of the lower surface of each of the plurality of second lower surface connection pads 430P1. The remaining portion of the lower surface of each of the plurality of second lower surface connection pads 430P1 may be on each of the plurality of conductive posts 200. The molding layer 250 may be in direct contact with the portion of the lower surface of each of the plurality of second lower surface connection pads 430P1 and the lower surface of the lowermost second redistribution insulating layer 410. An upper surface of the molding layer 250 and the upper surface of a conductive post 200 may be arranged at the same vertical level and thus may be coplanar with each other.

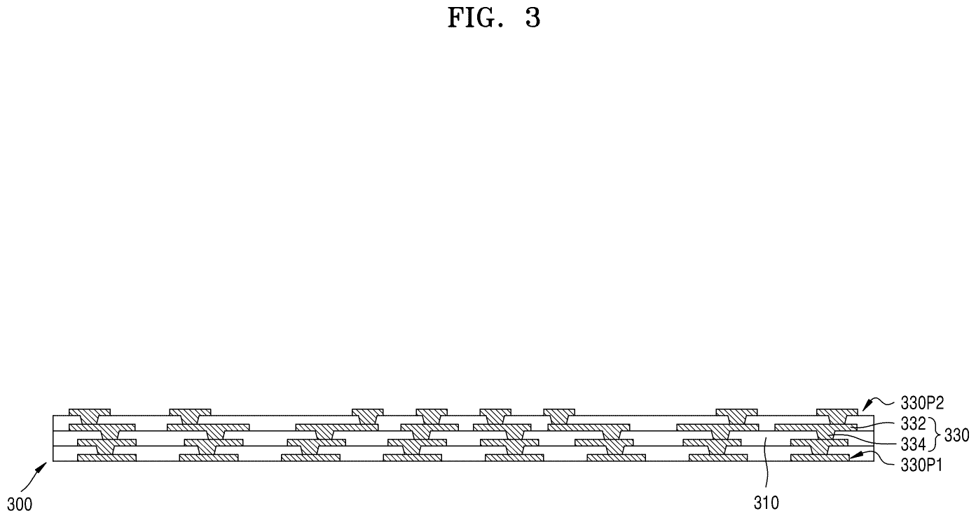

FIGS. 3 to 12 are cross-sectional views showing a method of manufacturing a semiconductor package, according to one or more embodiments. The semiconductor package manufactured through this method may be or correspond to the semiconductor package 1 shown in FIG. 1, and thus, duplicate descriptions may be omitted and the same reference numbers may be used herebelow.

Referring to FIG. 3, the first redistribution insulating layer 310 and the first wiring structure 300 including the plurality of first redistribution patterns 330 including the plurality of first redistribution line patterns 332 and the plurality of first redistribution vias 334 may be formed on a support substrate. The support substrate may be a semiconductor substrate, a glass substrate, a ceramic substrate, or a plastic substrate. In embodiments, after a release film is attached onto the support substrate, the first wiring structure 300 may be formed.

The first redistribution line patterns 332 may be formed on the support substrate. The first redistribution line patterns 332 formed on the support substrate may be the plurality of first lower surface connection pads 330P1. Afterwards, after a first preliminary redistribution insulating layer covering the first redistribution line patterns 332 is formed on the support substrate, the first redistribution insulating layer 310 having a plurality of first via holes may be formed by removing a portion of the first preliminary redistribution insulating layer through an exposure process and a development process. The plurality of first via holes may each be formed to have a horizontal width that decreases from the upper surface of the first redistribution insulating layer 310 toward the lower surface thereof. In embodiments, the lower surfaces of the plurality of first lower surface connection pads 330P1 and the lower surface of the first redistribution insulating layer 310 may be arranged at the same vertical level and thus may be coplanar with each other.

After a first redistribution conductive layer is formed on the first redistribution insulating layer 310, the first redistribution conductive layer may be patterned to further form the first redistribution patterns 330 including the first redistribution line patterns 332 and the first redistribution vias 334. The first redistribution vias 334 may be portions of the first redistribution patterns 330, which fill the plurality of first via holes, and the first redistribution line patterns 332 may be portions of the first redistribution patterns 330, which are above the upper surface of the first redistribution insulating layer 310.

The first redistribution vias 334 may each be formed to have a horizontal width that decreases from the upper surface of the first redistribution insulating layer 310 toward the lower surface thereof. Because the first redistribution patterns 330 including the first redistribution line patterns 332 and the first redistribution vias 334 are formed by patterning the first redistribution conductive layer, at least some of the first redistribution line patterns 332 formed on the first redistribution insulating layer 310 having the plurality of first via holes may be integrally formed with at least some of the first redistribution vias 334.

Afterwards, the first wiring structure 300 may be formed by repeatedly forming the first redistribution insulating layer 310 and the first redistribution patterns 330. The first redistribution line patterns 332 formed to be disposed on the upper surface of the first wiring structure 300 may be the plurality of first upper surface connection pads 330P2. In embodiments, the plurality of first upper surface connection pads 330P2 may be formed to protrude from the upper surface of the uppermost first redistribution insulating layer 310. In embodiments, when the first wiring structure 300 is formed to include the plurality of first redistribution insulating layers 310 that are stacked in the vertical direction, the plurality of first upper surface connection pads 330P2 may be the first redistribution line patterns 332 formed to be disposed on the upper surface of the uppermost first redistribution insulating layer 310.

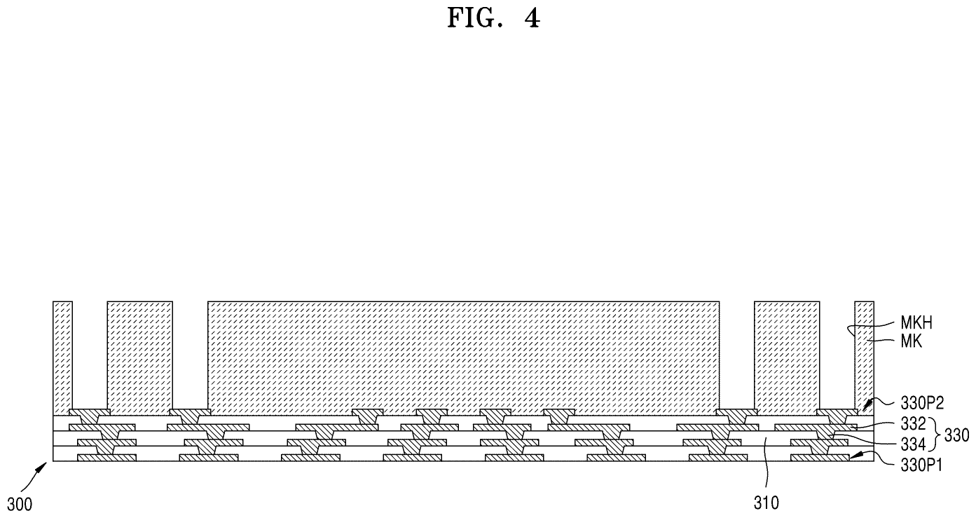

Referring to FIG. 4, a mask pattern MK having a plurality of mask holes MKH may be formed on the first wiring structure 300. For example, the mask pattern MK may be formed of photoresist. The plurality of mask holes MKH may correspond to some of the plurality of first upper surface connection pads 330P2. The plurality of mask holes MKH may penetrate the mask pattern MK. A portion of the upper surface of a first upper surface connection pad 330P2 may be exposed at a bottom of each of the plurality of mask holes MKH. The plurality of mask holes MKH may correspond to the plurality of conductive posts 200 shown in FIG. 1.

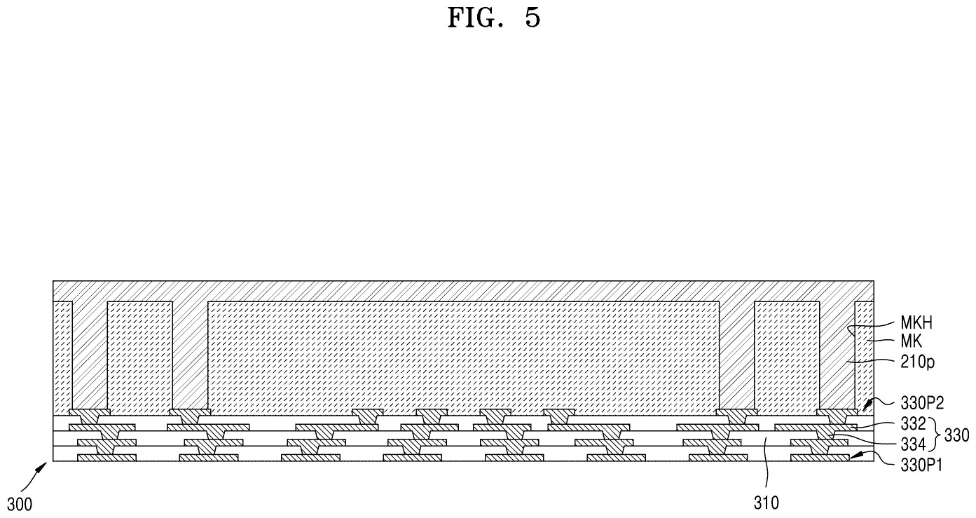

Referring to FIG. 5, a conductive filling material layer 210p may be formed on the mask pattern MK and fill the plurality of mask holes MKH. The conductive filling material layer 210p may be formed to fill all of the plurality of mask holes MKH. The conductive filling material layer 210p may include, for example, copper or a copper alloy.

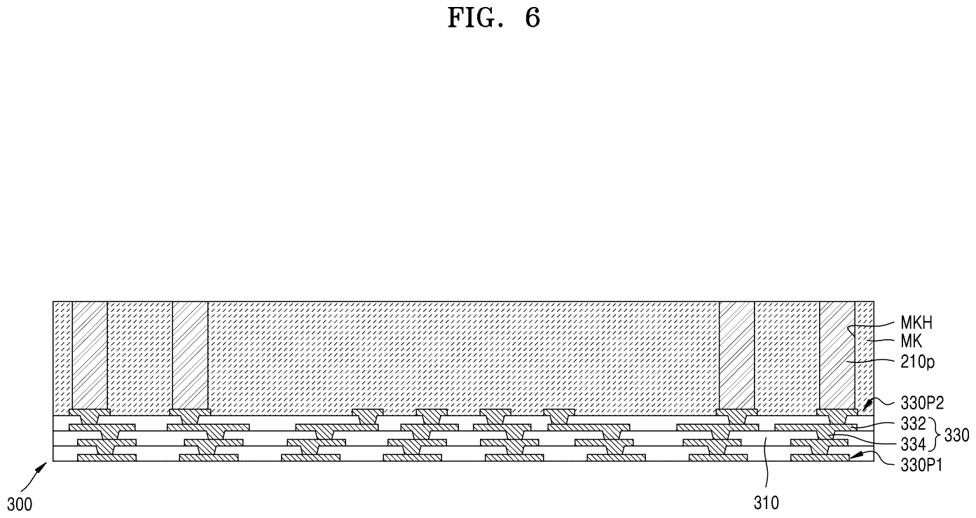

Referring to FIG. 6, a conductive post 200 (see FIG. 1) may be formed by removing an upper portion of the conductive filling material layer 210p such that the mask pattern MK is exposed. The conductive post 200 may include the body 210.

The plurality of conductive posts 200 may be formed by removing a portion of the conductive filling material layer 210p by performing a chemical-mechanical polishing (CMP_process. The plurality of conductive posts 200 may fill the plurality of mask holes MKH. During a process for forming the plurality of conductive posts 200, an upper portion of the mask pattern MK may also be removed.

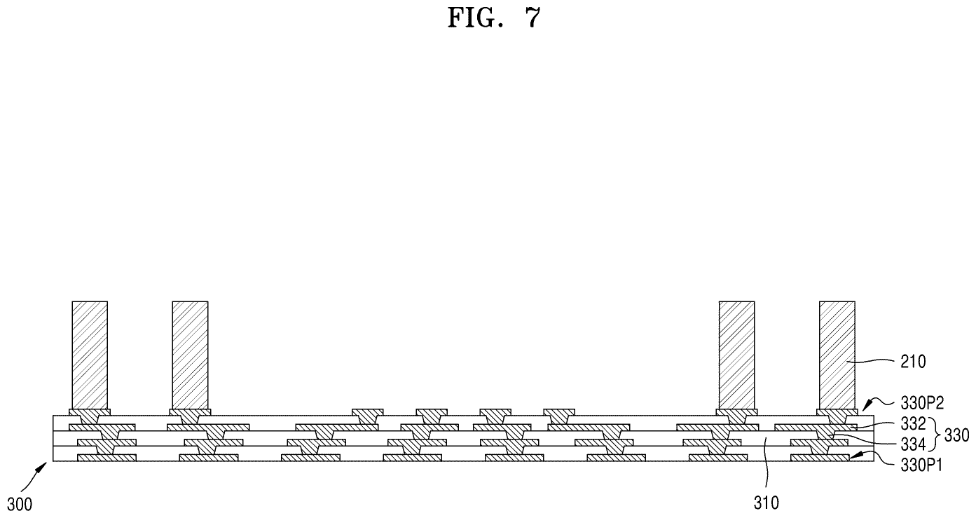

Referring to FIG. 7, the mask pattern MK may be removed from the first wiring structure 300. The side surfaces and upper surfaces of the plurality of conductive posts 200 may be exposed by removing the mask pattern MK.

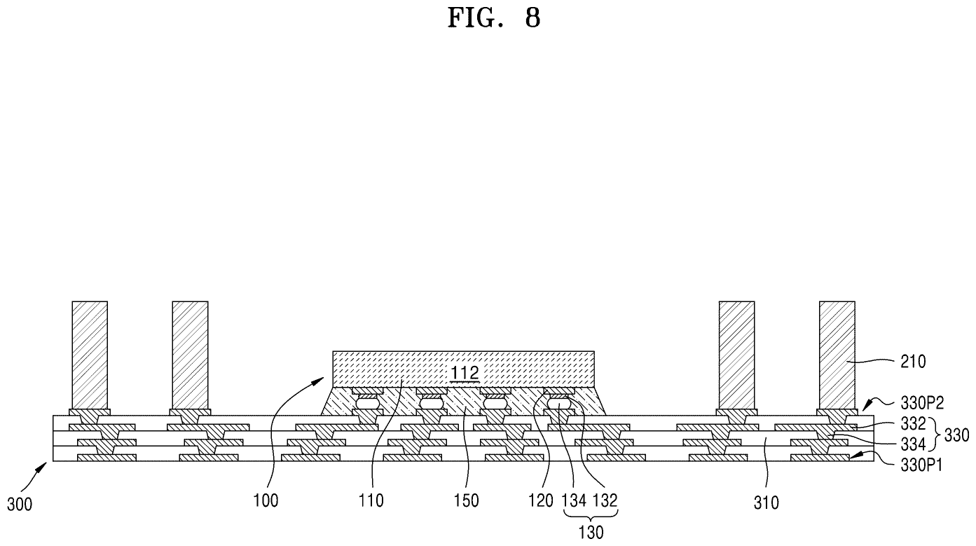

Referring to FIG. 8, the at least one semiconductor chip 100 including the plurality of chip pads 120 may be mounted on the first wiring structure 300. The semiconductor chip 100 may be attached onto the first wiring structure 300 so as to be spaced apart from a plurality of connection structures in the horizontal direction. In embodiments, the underfill layer 150 may be formed to fill the space between the at least one semiconductor chip 100 and the first wiring structure 300.

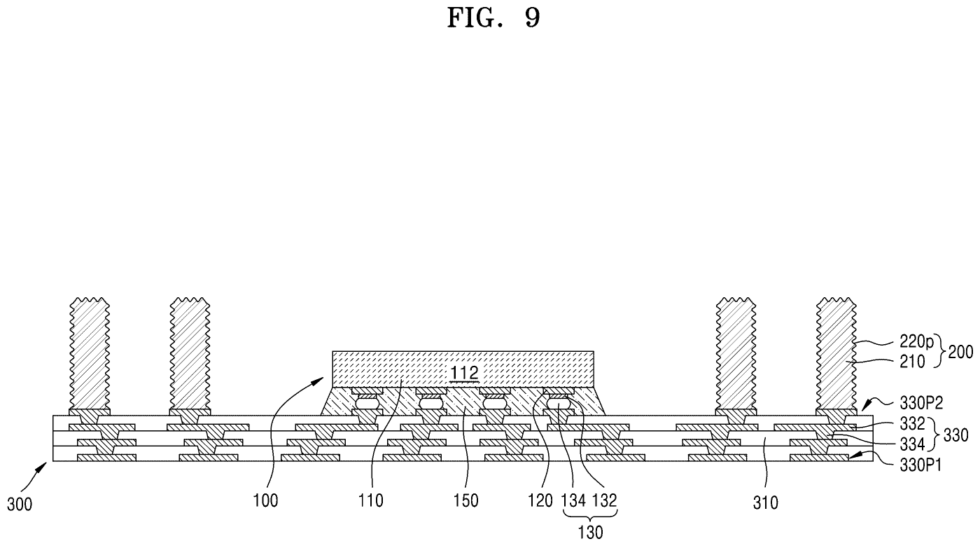

Referring to FIG. 9, a preliminary bonding surface 220p may be formed on the plurality of conductive posts 200. The preliminary bonding surface 220p may be formed by chemically etching the body 210. For example, the preliminary bonding surface 220p may be formed on the body 210 through dipping, and/or spraying, not being limited thereto. In some embodiments, dipping may form a preliminary bonding surface 220p covering the body 210 by dipping the body 210 in an etching solution, and spraying may spray the etching solution onto the surface of the body 210 to form a preliminary bonding surface 220p covering the body 210. At this time, the preliminary bonding surface 220p may include a rough surface. The preliminary bonding surface 220p may be formed on the side surface and the upper surface of the body 210. The preliminary bonding surface 220p may include the plurality of protrusions 221 (see FIG. 2) and the plurality of recesses 222 (see FIG. 2), and the plurality of protrusions 221 and the plurality of recesses 222 may constitute the rough surface. Characteristics of the plurality of protrusions 221 and the plurality of recesses 222 may be substantially the same as described above.

When the preliminary bonding surface 220p is formed through chemical etching, the preliminary bonding surface 220p may be not a separate thin layer but just the side surface of the body 210, in which case the body 210 and the preliminary bonding surface 220p may be a single continuum structure formed of the same metal or metal compound without a connection surface, a boundary or an interface therebetween.

Afterwards, a bake process for removing moisture from the first wiring structure 300 and the plurality of conductive posts 200 and/or a plasma treatment for particle removal and surface treatment may be performed. In embodiments, during a process of performing the bake process and/or the plasma treatment, an oxide film may be formed on the plurality of conductive posts 200.

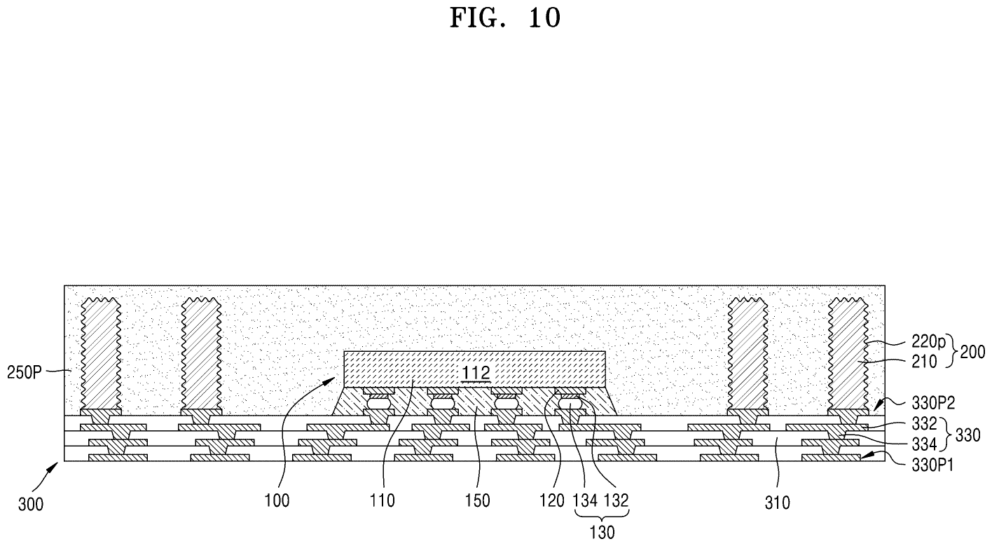

Referring to FIG. 10, a preliminary molding layer 250P surrounding the plurality of conductive posts 200 and the at least one semiconductor chip 100 may be formed on the first wiring structure 300. The preliminary molding layer 250P may be formed to have an upper surface at a vertical level that is higher than the upper surfaces of the plurality of conductive posts 200, to surround the upper surface of each of the plurality of conductive posts 200.

In embodiments, the preliminary bonding surface 220p may be in contact with the preliminary molding layer 250P, whereas the body 210 may not be in contact with the preliminary molding layer 250P. The preliminary bonding surface 220p may be arranged between the body 210 and the preliminary molding layer 250P. The body 210 and the preliminary molding layer 250P may be spaced apart from each other with the bonding surface 220 therebetween.

In embodiments, the preliminary molding layer 250P may be in contact with the preliminary bonding surface 220p. Because the preliminary bonding surface 220p includes the rough surface, a cross-sectional area where the preliminary molding layer 250P is in contact with the preliminary bonding surface 220p may increase. Because the cross-sectional area where the preliminary molding layer 250P is in contact with the preliminary bonding surface 220p increases, a bonding force between the preliminary molding layer 250P and the plurality of conductive posts 200 may increase.

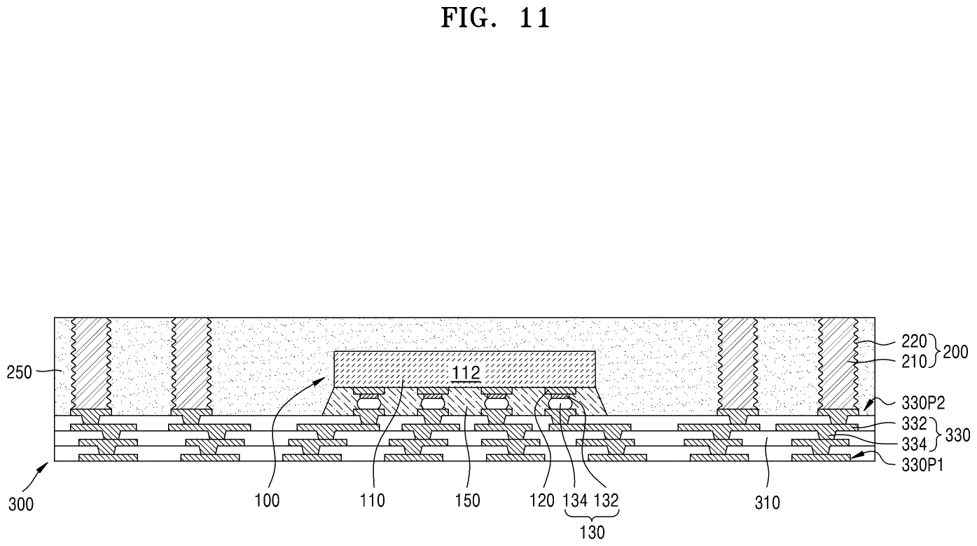

Referring to FIG. 11, the molding layer 250 may be formed by removing a portion of an upper portion of the preliminary molding layer 250P such that the upper surfaces of the plurality of conductive posts 200 are exposed. In embodiments, during a process of forming the molding layer 250, an upper portion of the plurality of conductive posts 200 may also be removed. For example, an upper portion of the body 210, a portion of the preliminary bonding surface 220p on the upper surface of the body 210 and a portion of the preliminary bonding surface 220p, on the side surface of the body 210 may be removed. In addition, the oxide film generated on each of the upper surfaces of the plurality of conductive posts 200 may also be removed during a process of removing the upper portion of the plurality of conductive posts 200.

The semiconductor package 1 of the disclosure may have improved structural stability and reliability by improving a stress and a bonding force between the plurality of conductive posts 200 and the molding layer 250.

Because the bonding surface 220 includes the rough surface, a cross-sectional area where the molding layer 250 is in contact with the bonding surface 220 may increase. Because the cross-sectional area where the molding layer 250 is in contact with the bonding surface 220 increases, a bonding force between the molding layer 250 and the plurality of conductive posts 200 may increase. Because the cross-sectional area where the molding layer 250 is in contact with the bonding surface 220 increases, delamination that occurs at an interface between the molding layer 250 and the plurality of conductive posts 200 may be reduced. The structural stability and reliability of the semiconductor package 1 may be improved by eliminating or minimizing the delamination that occurs at the interface between the molding layer 250 and the plurality of conductive posts 200.

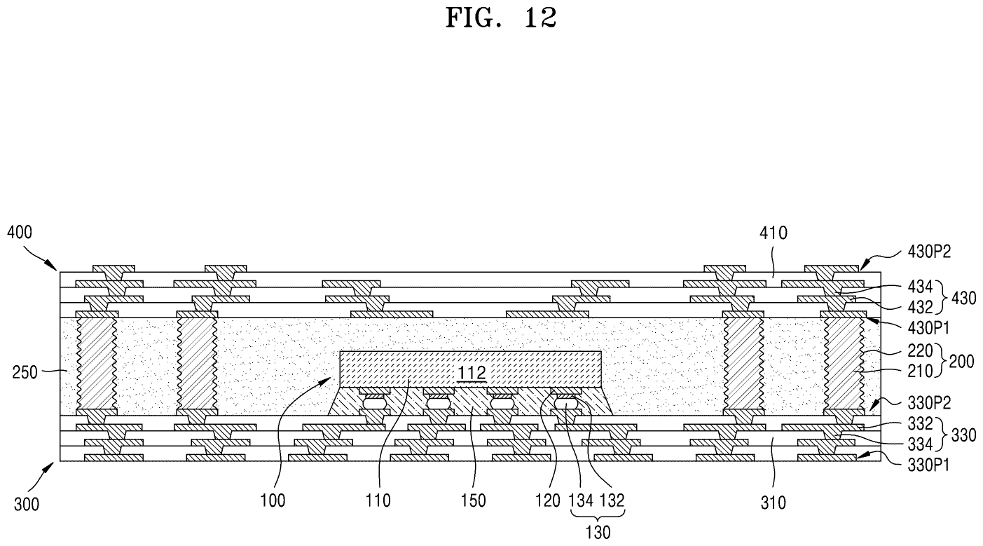

Referring to FIG. 12, the second redistribution structure 400 including the second redistribution insulating layer 410 and the plurality of second redistribution patterns 430 including the plurality of second redistribution line patterns 432 and the plurality of second redistribution vias 434 may be formed on the plurality of conductive posts 200 and the molding layer 250.

Afterwards, as shown in FIG. 1, the semiconductor package 1 may be formed by attaching the plurality of external connection terminals 500 to the plurality of first lower surface connection pads 330P1.

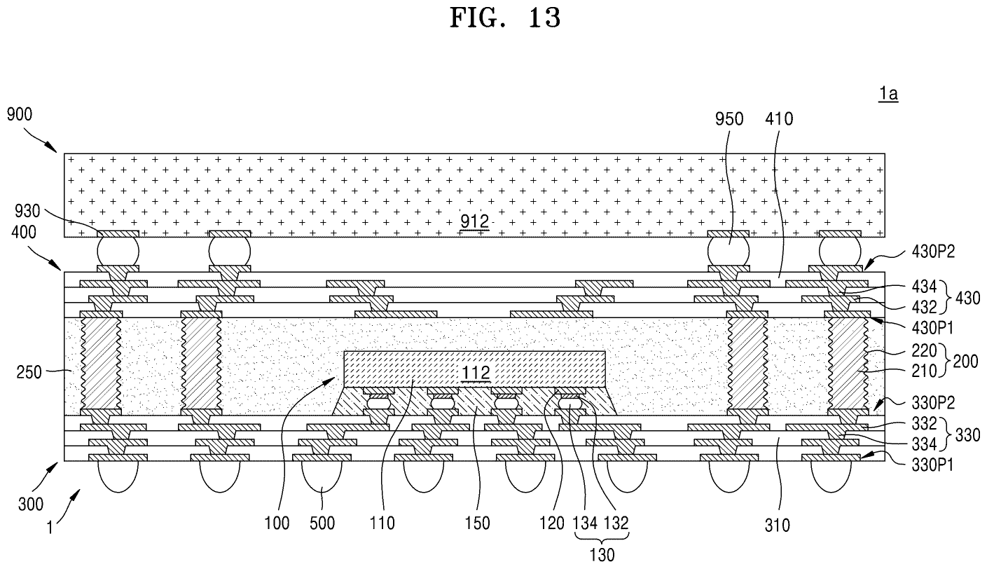

FIG. 13 is a cross-sectional view of a semiconductor package according to one or more embodiments.

Referring to FIG. 13, a semiconductor package la of the disclosure may include a lower package 1 and an upper package 900 attached onto the lower package 1. The semiconductor package la may be a PoP. The lower package 1 may be the semiconductor package 1 shown in FIG. 1.

The upper package 900 may have an upper semiconductor chip having an upper semiconductor device 912 and a plurality of upper connection pads 930. The upper package 900 may be electrically connected to the lower package 1 by a plurality of package connection terminals 950 arranged between the plurality of upper connection pads 930 and the plurality of second upper surface connection pads 430P2.

The upper package 900 may be attached onto the lower package 1 such that the plurality of upper connection pads 930 face the lower package 1. For example, the upper package 900 may be electrically connected to the plurality of first redistribution patterns 330 of the first wiring structure 300 or a plurality of first wiring patterns 380 of a first wiring structure 350 through the plurality of package connection terminals 950 attached to the plurality of upper connection pads 930, the plurality of second redistribution patterns 430, and the plurality of conductive posts 200.

In embodiments, the upper semiconductor device 912 may be a memory device, and the upper semiconductor chip may be a memory semiconductor chip. For example, the memory device may be a non-volatile memory device, such as flash memory, PRAM, MRAM, FeRAM, or RRAM. In some embodiments, the memory device may be a volatile memory device, such as DRAM or SRAM.

The upper package 900 may include one or more upper semiconductor chips. The upper semiconductor chip may be mounted in the upper package 900 by using a flip chip method, or may be electrically connected through a bonding wire, and may be mounted on by using a die attach film (DAF). The upper package 900 may include a plurality of upper semiconductor chips that are spaced apart from each other in the horizontal direction, or may include a plurality of upper semiconductor chips that are stacked in the vertical direction. Alternatively, the upper package 900 may include a plurality of upper semiconductor chips that are electrically connected to each other through a through electrode and are stacked in the vertical direction. Alternatively, the upper package 900 may be one semiconductor chip.

The upper package 900 may correspond to any type of semiconductor package that includes at least one upper semiconductor chip having the upper semiconductor device 912 and includes the plurality of upper connection pads 930 on a lower side thereof so as to be electrically connected to the lower package 1.

While the disclosure has been particularly shown and described with reference to embodiments thereof, it will be understood that various changes in form and details may be made therein without departing from the spirit and scope of the following claims.

What is claimed is:

1. A semiconductor package comprising:
a first wiring structure comprising at least one first wiring pattern and a first insulating layer comprising the first wiring pattern therein;
a second wiring structure comprising at least one second wiring pattern and a second insulating layer comprising the second wiring pattern therein;
a semiconductor chip between the first wiring structure and the second wiring structure;
a molding layer between the first wiring structure and the second wiring structure, the molding layer comprising the semiconductor chip therein; and
a conductive post penetrating the molding layer and configured to electrically connect the first wiring structure to the second wiring structure,
wherein the conductive post comprises:
a body extended through the molding layer in a vertical direction; and
a bonding surface on a side surface of the body and having a greater roughness than an upper surface and a lower surface of the conductive post.

2. The semiconductor package of claim 1, wherein the bonding surface is on an entire side surface of the body.

3. The semiconductor package of claim 1, wherein the bonding surface comprises:
at least one protrusion protruding toward the molding layer; and
at least one recess.

4. The semiconductor package of claim 3, wherein the protrusion comprises a plurality of protrusions, and the recess comprises a plurality of recesses respectively arranged between the plurality of protrusions that are adjacent to each other,
wherein sizes or shapes are different between the plurality of protrusions.

5. The semiconductor package of claim 4, wherein the plurality of protrusions and the plurality of recesses are arranged irregularly.

6. The semiconductor package of claim 3, wherein the molding layer is in contact with the protrusion and the recess.

7. The semiconductor package of claim 1, wherein a thickness of the bonding surface in a horizontal direction is greater than or equal to 10 nm.

8. The semiconductor package of claim 1, further comprising an oxide film on the bonding surface.

9. The semiconductor package of claim 1, wherein the body and the molding layer are spaced apart from each other with the bonding surface therebetween.

10. A method of manufacturing a semiconductor package, the method comprising:
forming a first wiring structure comprising at least one first wiring pattern and a first insulating layer comprising the first wiring pattern therein;
forming a conductive post on the first wiring structure;
mounting a semiconductor chip on the first wiring structure;
forming a bonding surface on the conductive post;
forming a molding layer on the conductive post and the semiconductor chip; and
forming, on the molding layer, a second wiring structure comprising at least one second wiring pattern and a second insulating layer comprising the second wiring pattern therein,
wherein the bonding surface has a greater roughness than an upper surface and a lower surface of the conductive post.

11. The method of claim 10, wherein the forming of the bonding surface on the conductive post comprises forming the bonding surface having a greater roughness than the upper surface and the lower surface of the conductive post through chemical etching.

12. The method of claim 10, wherein the forming of the bonding surface on the conductive post comprises forming a plurality of protrusions protruding toward the molding layer and a plurality of recesses respectively arranged between the plurality of protrusions that are adjacent to each other.

13. The method of claim 12, wherein the forming of the bonding surface on the conductive post comprises forming the plurality of protrusions to have different sizes or shapes.

14. The method of claim 12, wherein the forming of the bonding surface on the conductive post comprises forming the plurality of protrusions and the plurality of recesses to be arranged irregularly.

15. The method of claim 12, wherein the forming of the molding layer comprises forming the molding layer to be in contact with the plurality of protrusions and the plurality of recesses.

16. The method of claim 10, further comprising forming an oxide film on the bonding surface.

17. A semiconductor package comprising:
a first wiring structure comprising at least one first wiring pattern and a first insulating layer comprising the first wiring pattern therein;
a second wiring structure comprising at least one second wiring pattern and a second insulating layer comprising the second wiring pattern therein;
a semiconductor chip between the first wiring structure and the second wiring structure;
a molding layer between the first wiring structure and the second wiring structure, the molding layer comprising the semiconductor chip therein; and
a conductive post penetrating the molding layer and configured to electrically connect the first wiring structure to the second wiring structure,
wherein the conductive post comprises:
a body extended through the molding layer in a vertical direction; and
a bonding surface on the body, the bonding surface comprising at least one protrusion protruding toward the molding layer and at least one recess.

18. The semiconductor package of claim 17, wherein the molding layer is in contact with the protrusion and the recess.

19. The semiconductor package of claim 17, wherein the bonding surface is on an entire side surface of the body.

20. The semiconductor package of claim 17, wherein the protrusion comprises a plurality of protrusions, and the recess comprises a plurality of recesses respectively arranged between the plurality of protrusions that are adjacent to each other,
wherein sizes or shapes are different between the plurality of protrusions.
